(19) United States
(12) Patent Application Publication
(10) Pub. No.: US 2023/0392878 A1
(43) Pub. Date: Dec. 7, 2023

(54) EXPOSED TUBE COLD PLATE STRUCTURE

(71) Applicant: ASIA VITAL COMPONENTS CO., LTD., New Taipei City (TW)

(72) Inventors: Dan-Jun Chen, New Taipei City (TW); Guo-Hui Li, New Taipei City (TW); Chuan-Wen Huang, New Taipei City (TW)

(21) Appl. No.: 18/112,502

(22) Filed: Feb. 22, 2023

(30) Foreign Application Priority Data
Jun. 6, 2022 (TW) 111120876

(51) Int. Cl. F28F 1/14; F28D 15/00; F28D 1/047

(52) U.S. Cl. CPC F28F 1/14; F28D 15/00; F28D 1/0475; F28D 2021/0028

(57) ABSTRACT

An exposed tube cold plate structure includes a plate body and a water cooling tube. The plate body is formed with a groove. The water cooling tube is pressed and inlaid in the groove. The water cooling tube has a water cooling tube passage for a working medium to flow through. The water cooling tube passage has a passage inner wall. Multiple raised bodies and multiple channels are annularly alternately disposed on the passage inner wall for greatly enlarging the contact area between the passage inner wall and the working medium. In addition, the working medium flows through the water cooling tube passage in a state of turbulent flow so as to enhance the heat exchange amount of the cold plate.

This application claims the priority benefit of Taiwan patent application number 111120876 filed on Jun. 6, 2022.

### BACKGROUND OF THE INVENTION

### 1. Field of the Invention

The present invention relates generally to a cold plate, and more particularly to an exposed tube cold plate structure.

### 2. Description of the Related Art

An exposed tube cold plate has a substrate (such as copper plate or aluminum plate). The substrate is CNC processed, whereby a groove with a predetermined configuration is formed on the substrate. A bent copper tube with a configuration corresponding to the groove is then inlaid (or embedded) into the groove. A high heat conductivity epoxy resin can be selectively filled between the copper tube and the groove of the substrate. Alternatively, the copper tube can be soldered in the groove by means of solder paste to enhance the strength of the cold plate and help in transferring heat. When the copper tube is inlaid (embedded) into the groove, the copper tube is flattened at the same time. Then the surface of the copper tube is milled and processed, whereby the exposed surface of the copper tube is flush with the surface of the substrate. In this case, the copper tube can direct contact a heat generation component to directly conduct the heat away. The passage of the seamless copper tube serves as a water passage for a working medium to flow through. The copper tube is free from the risk of leakage of the liquid and can be double-face mounted on the heat generation component.

FIGS. 1A to 1C show a conventional exposed tube cold plate including a cold plate substrate 11 and a copper tube 12. The cold plate substrate 11 is processed to form a groove 13 thereon by means of CNC grooving technique. The copper tube 12 is then pressed and inlaid into the groove 13. Then an exposed surface of the copper tube 12 is flattened or plain milled by means of surface profile processing such as pressing or milling, whereby the exposed surface of the copper tube 12 is flush with the cold plate substrate 11 for contacting the heat generation component. The copper tube 12 has an internal passage 121 passing through the copper tube 12 between two ends thereof. A working medium 14 such as water or coolant or ethanol flows through the passage 121 to transfer heat.

However, the direct contact area of the conventional copper tube 12 (as shown in FIG. 1A) with the heat generation component is quite small so that the heat of the heat generation component cannot be fully carried away. Especially, the copper tube 12 is bent into a coiled winding configuration (as shown in FIG. 1B) or S-shaped winding configuration and disposed on the cold plate substrate 11 for increasing the contact area of the copper tube 12 with the heat generation component. Also, by means of the elongated length of the winding tube body of the copper tube 12, the flowing time of the working medium is prolonged to improve heat exchange effect.

However, in the above conventional copper tube 12, the inner wall of the passage 121 is a polished face without any feature. Under such circumstance, the working medium will flow through the passage 121 of the copper tube 12 in a stratified state. That is, the working medium will flow through the passage 121 as laminar flows in parallel to each other without mixing with each other. The working medium 14 positioned in the substantially central portion of the passage 121 will flow by a faster speed, while the working medium 14 positioned near the inner wall of the passage 121 will flow by a slower speed (as shown in FIG. 1C). As a result, only the working medium 14 near the inner wall of the passage 121 will achieve heat exchange effect, while the working medium 14 at the center of the passage 121 will fast flow through the passage 121 and cannot achieve useable heat exchange effect. Therefore, the total heat exchange amount is reduced and the heat exchange performance of the cold plate is poor.

It is therefore tried by the applicant to provide an exposed tube cold plate structure to solve the above problem existing in the conventional cold plate.

### SUMMARY OF THE INVENTION

It is therefore a primary object of the present invention to provide an exposed tube cold plate structure including a plate body and a water cooling tube. The plate body is formed with a groove. The water cooling tube is pressed and inlaid in the groove. The water cooling tube has a water cooling tube passage. The water cooling tube passage has a passage inner wall. Multiple raised bodies and multiple channels are disposed on the passage inner wall to enhance the heat exchange amount of the cold plate.

It is a further object of the present invention to provide the above exposed tube cold plate structure, in which the raised bodies protrude from the passage inner wall to a center of the water cooling tube passage. Therefore, the thickness of the wall of the water cooling tube is not thinned so that the wall of the water cooling tube is not apt to break and damage. Accordingly, the structural strength of the water cooling tube can be maintained.

To achieve the above and other objects, the exposed tube cold plate structure of the present invention includes a plate body and a water cooling tube. The plate body is formed with a groove. The water cooling tube is disposed in the groove. The water cooling tube has a first end, a second end and a water cooling tube passage. The water cooling tube passage passes through the water cooling tube from the first end to the second end. The water cooling tube passage has a passage inner wall. Multiple raised bodies are annularly disposed on the passage inner wall at intervals. Each two adjacent raised bodies define therebetween a channel. The raised bodies and the channels serve to enhance heat exchange amount of the exposed tube cold plate structure.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIGS. 1A to 1C show a conventional exposed tube cold plate;

FIG. 2A is a perspective exploded view of the exposed tube cold plate structure of the present invention;

FIG. 2B is a perspective assembled view of the exposed tube cold plate structure of the present invention;

FIG. 3A is a perspective view showing that the raised bodies and the channels in the passage of the water cooling tube of the present invention are arranged in a twisting angle;

FIG. 3B is a top view according to FIG. 3A;

FIG. 3C is an axially sectional view of a segment of FIG. 3A; and

FIG. 3D is a top view of the segment of FIG. 3C.

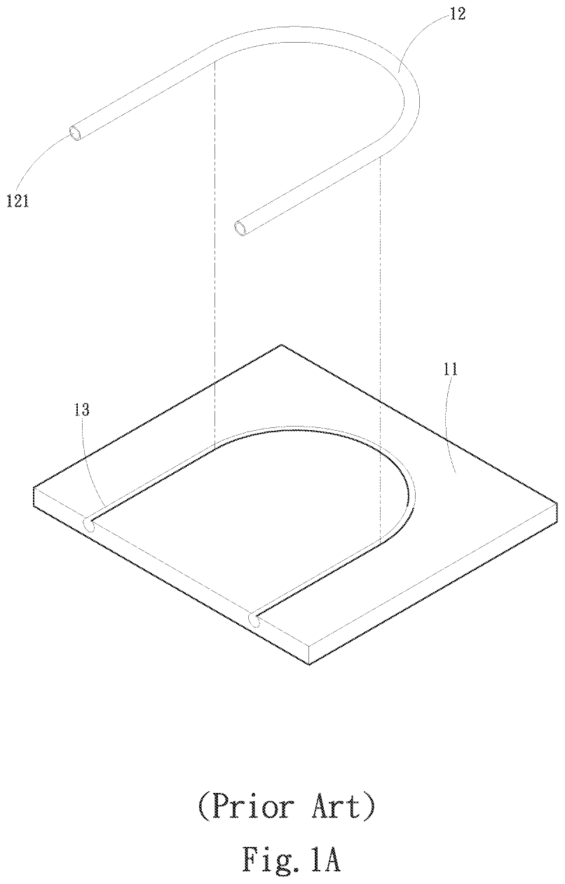

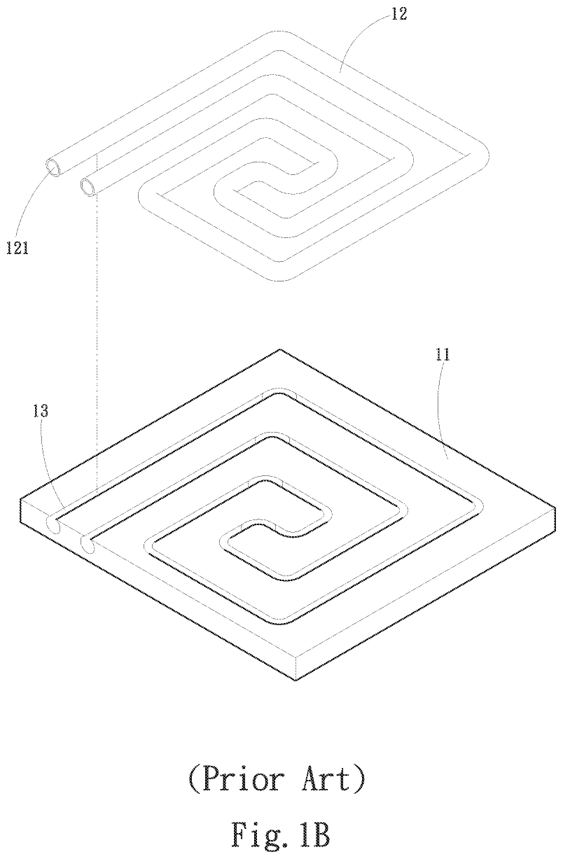

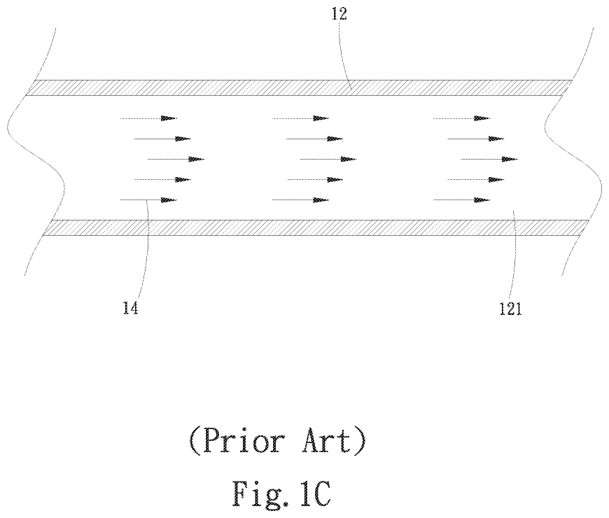

### DETAILED DESCRIPTION OF THE PREFERRED EMBODIMENTS

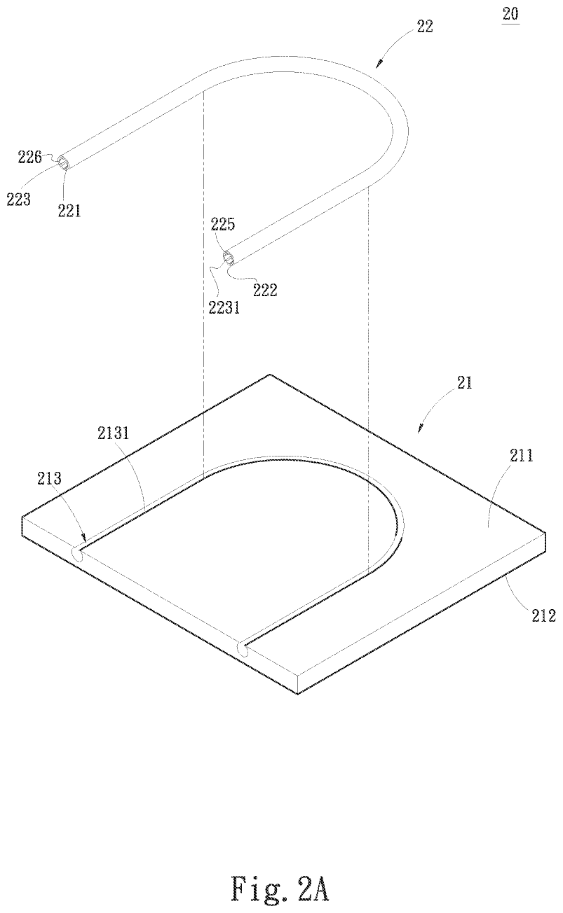

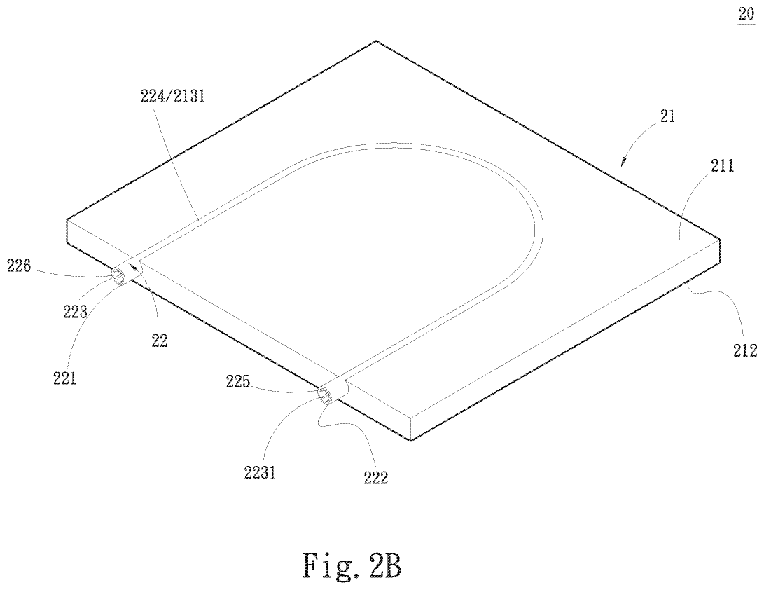

Please refer to FIGS. 2A and 2B. FIG. 2A is a perspective exploded view of the exposed tube cold plate structure of the present invention. FIG. 2B is a perspective assembled view of the exposed tube cold plate structure of the present invention. As shown in the drawings, the cold plate 20 of the present invention includes a plate body 21 and a water cooling tube 22. The plate body 21 is selectively made of metal material with higher heat conductivity, such as copper, aluminum, stainless steel, titanium or titanium alloy. The water cooling tube 22 is selectively made of copper, copper alloy, aluminum or aluminum alloy. The plate body 21 has at least one surface such as an upper surface 211 and a lower surface 212. Any of the upper and lower surfaces 211, 212 is selectively formed with a groove 213. In this embodiment, the groove 213 is formed on the upper surface 211 and has an open side 2131 flush with the upper surface 211. In a practical embodiment, a processing machine such as a CNC device is used to process and groove the upper surface 211 along a predetermined profile to form the groove 213. The water cooling tube 22 is formed with a configuration in adaptation to the configuration of the groove 213 and is inlaid in the groove 213 by means of pressing. The water cooling tube 22 has an exposed surface 224 exposed to outer side through the open side 2131 of the groove 213. The exposed surface 224 is treated by means of surface profile processing (such as pressing or milling), whereby the exposed surface 224 is flush with the upper surface 211 of the plate body 21 for contacting a heat generation component.

In the drawings, the groove 213 and the water cooling tube 22 are U-shaped. However, in practice, the configuration of the groove 213 and the water cooling tube 22 is not limited. Alternatively, the groove 213 and the water cooling tube 22 can be coil-shaped, S-shaped or windingly shaped (not shown).

Please further refer to FIGS. 2A and 2B. The water cooling tube 22 has a first end 221, a second end 222 and a water cooling tube passage 223. In this embodiment, the first and second ends 221, 222 are, but not limited to, protruded from one side of the plate body 21 (from the same side or different sides). Alternatively, the first and second ends 221, 222 are flush with one side of the plate body 21 (not shown). The water cooling tube passage 223 passes through the water cooling tube 22 from the first end 221 to the second end 222. The water cooling tube passage 223 has a passage inner wall 2231. Multiple raised bodies 225 are annularly disposed on the passage inner wall 2231 at intervals. The raised bodies 225 extend from the first end 221 to the second end 222. A working medium 30 such as water or coolant or ethanol flows into the water cooling tube passage 223 from any of the first and second ends 221, 222 and then flows through the water cooling tube passage 223 and then flows out of the water cooling tube passage 223 from the other end thereof.

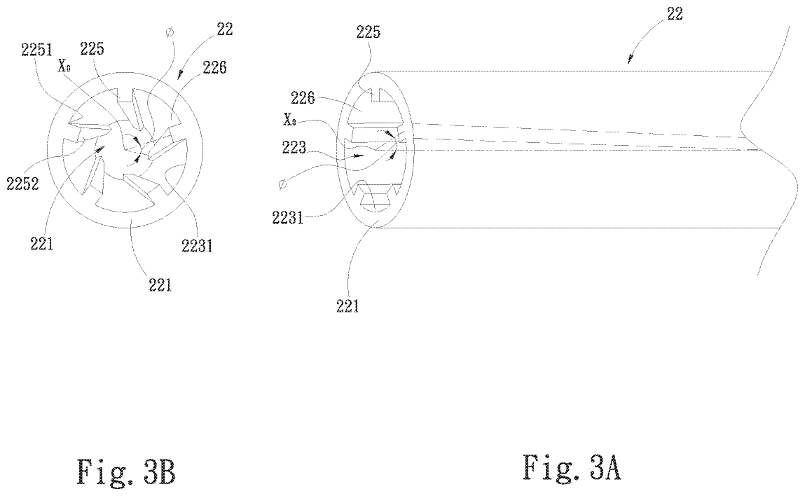

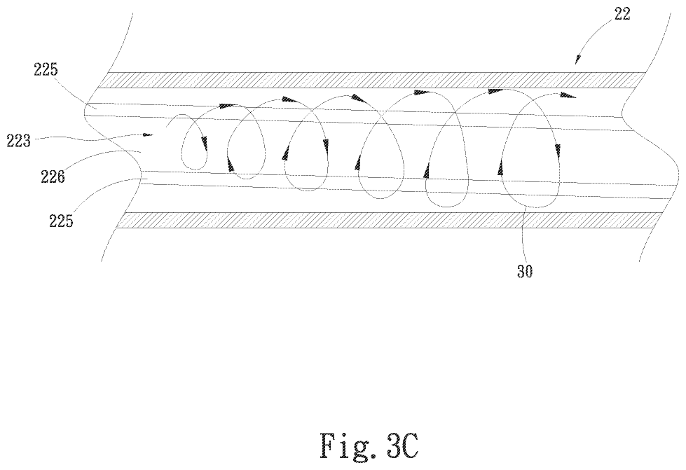

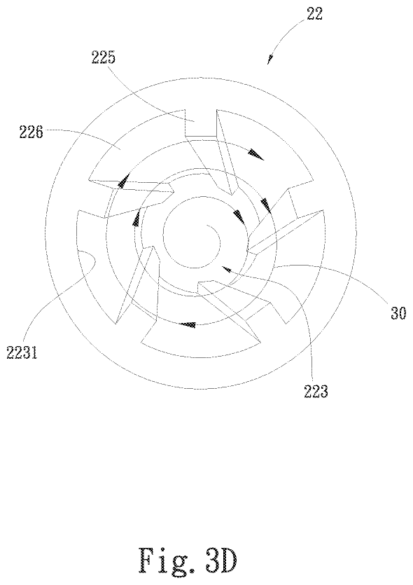

Please now refer to FIGS. 3A and 3B. FIG. 3A is a perspective view showing that the raised bodies and the channels in the passage of the water cooling tube of the present invention are arranged in a twisting angle. FIG. 3B is a top view according to FIG. 3A. Also referring to FIGS. 2A and 2B, the raised bodies 225 (such as ribs or fins) protrude from the passage inner wall 2231 toward a center X₀ of the water cooling tube passage 223. Each two adjacent raised bodies 225 define therebetween a channel 226. Each raised body 225 has a fixed end 2251 and a free end 2252. The fixed end 2251 is connected with the passage inner wall 2231.

The free end 2252 protrudes from the passage inner wall 2231 toward the center X₀ of the water cooling tube passage 223. The water cooling tube 22 and the raised bodies 225 can be integrally formed or non-integrally formed. In the case that the water cooling tube 22 and the raised bodies 225 are integrally formed, the raised bodies 225 can be formed by means of drawing the water cooling tube 22 with a mold. In the case that the water cooling tube 22 and the raised bodies 225 are non-integrally formed, the water cooling tube 22 and the raised bodies 225 are connected with each other by a connection means (such as welding, adhesion or engagement). The raised bodies 225 and the channels 226 are disposed in the water cooling tube passage 223 by a twisting angle ϕ. That is, all the raised bodies 225 and the channels 226 extend from the first end 221 of the water cooling tube 22 to the second end 222 in a twisted and inclined state.

Substantially, the raised bodies 225 and the channels 226 are disposed in the water cooling tube passage 223 by a twisting angle ϕ in such a manner that one or both of the first and second ends 221, 222 of the water cooling tube 22 are twisted in different directions (clockwise and counterclockwise). Alternatively, the raised bodies 225 and the channels 226 can be integrally formed (by means of such as drawing the water cooling tube 22 with a mold) or non-integrally formed (such as welding, adhesion or engagement) in the water cooling tube passage 223 by the twisting angle ϕ. Then the water cooling tube 22 is bent in adaptation to the configuration of the groove 213 and pressed and inlaid into the groove 23.

As aforesaid, the raised bodies 225 and the channels 226 are disposed in the water cooling tube passage 223 by a twisting angle ϕ. This can eliminate the shortcoming of the conventional cold plate that the working medium flows through the passage as laminar flows in a stratified state. By means of the present invention, the working medium 30 in the water cooling tube passage 223 can be better mixed to become turbulent flow so as to enhance the heat exchange efficiency.

Moreover, in the above embodiments, the raised bodies 225 inward protrude from the passage inner wall 2231 to the center of the water cooling tube passage 223. The channel 226 is defined between each two adjacent raised bodies 225 rather than formed on the passage inner wall 2231 by means of grooving the passage inner wall 2231. Therefore, the thickness of the wall of the water cooling tube 22 will not be thinned so that the wall of the water cooling tube 22 is not apt to break and damage. Accordingly, the structural strength of the water cooling tube 22 can be maintained.

Please further refer to FIGS. 3C and 3D. Also referring to FIGS. 2A and 2B, according to Newton's law of cooling, the total effect of convection is described as follows:

Q=h×A×Δt, wherein:

Q is heat exchange amount (or so-termed heat conductivity), h is surface heat exchange coefficient (or so-termed convection heat transfer coefficient), A is heat exchange surface area (or so-termed contact area) and Δt is fluid temperature difference (T-T′).

With respect to the same configuration and specification of the cold plate (including the size of the plate body and the bending configuration of the water cooling tube) and the same working medium and flow amount of the working medium, there are two means for enhancing the heat exchange performance of the cold plate 20. One is to increase the heat exchange area A in the water cooling tube 22 of the cold plate 20. The other is to increase the surface heat exchange coefficient h of the cold plate 20.

Therefore, when the working medium 30 flows through the water cooling tube 22, during the flowing process, the working medium 30 near the passage inner wall 2231 is disturbed by the twisted raised bodies 225 and the twisted channels 226 to flow in the twisting direction as a vortex in a coiled scattering state. The working medium 30 then develops to flow through the water cooling tube passage 223 in a state of mixed turbulent flows. In comparison with the working medium flowing through the conventional cold plate as laminar flows, the working medium 30 flowing through the cold plate of the present invention in the state of turbulent flows can greatly increase the surface heat exchange coefficient h of the passage inner wall 2231 in contact with the working medium 30 so as to increase the surface heat exchange coefficient h in the water cooling tube passage 223. Moreover, the raised/recessed structures of the raised bodies 225 and the channels 226 can enlarge the contact area between the water cooling tube passage 223 and the working medium 30 so as to enlarge the heat exchange surface area A of the cold plate 20. In the case that both the surface heat exchange coefficient h and the heat exchange surface area A are increased, the heat exchange amount of the cold plate 20 is greatly increased.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. An exposed tube cold plate structure comprising:
a plate body formed with a groove; and
a water cooling tube disposed in the groove, the water cooling tube having a first end, a second end and a water cooling tube passage, the water cooling tube passage passing through the water cooling tube from the first end to the second end, the water cooling tube passage having a passage inner wall, multiple raised bodies being annularly disposed on the passage inner wall at intervals, each two adjacent raised bodies defining therebetween a channel, the raised bodies and the channels serving to enhance heat exchange amount of the exposed tube cold plate structure.

2. The exposed tube cold plate structure as claimed in claim 1, wherein the raised bodies protrude from the passage inner wall toward a center of the water cooling tube passage, each raised body having a fixed end and a free end, the fixed end being connected with the passage inner wall, the free end protruding toward the center of the water cooling tube passage.

3. The exposed tube cold plate structure as claimed in claim 1, wherein the raised bodies extend from the first end to the second end.

4. The exposed tube cold plate structure as claimed in claim 1, wherein the plate body has a surface, the groove being formed on the surface and having an open side, the water cooling tube having an exposed surface exposed to outer side through the open side of the groove, the exposed surface being flush with the surface of the plate body.
